(19) United States
(12) Patent Application Publication
(10) Pub. No.: US 2001/0053587 A1
(43) Pub. Date: Dec. 20, 2001

(54) Apparatus for supplying a liquid raw material and method of manufacturing a copper layer using the same

(76) Inventor: Sung Gyu Pyo, Ichon-Shi (KR)

Correspondence Address: MARSHALL, O'TOOLE, GERSTEIN, MURRAY & BORUN, 6300 SEARS TOWER, 233 SOUTH WACKER DRIVE, CHICAGO, IL, 60606-6402, US

(21) Appl. No.: 09/821,979

(22) Filed: Mar. 30, 2001

(30) Foreign Application Priority Data
Jun. 15, 2000 (KR) 2000-32923

(51) Int. Cl. C30B 1/00

(52) U.S. Cl. 438/496

(57) ABSTRACT

An apparatus and method for supplying a liquid raw material are disclosed in which a raw material in a liquid state is converted into a gas state for supplying the raw material to a process chamber to manufacture a metal layer on a semiconductor wafer. The apparatus includes a carrier gas supply tube having a narrowed portion, a sprayer connected to the narrowed portion of the carrier gas supply tube and having a nozzle which protrudes into the carrier gas supply tube, a precursor supply tube connected to the sprayer, and a showerhead connected to an end of the carrier gas supply tube.

### FIELD OF THE INVENTION

The invention relates generally to semiconductor devices, and more particularly, to an apparatus for supplying a liquid raw material and a method of manufacturing a copper layer using the same.

### BACKGROUND OF THE INVENTION

Generally, as a semiconductor device becomes more highly integrated and faster, copper (Cu) is commonly used as a metal wiring material of the device. Copper (Cu) may be deposited by using methods such as physical vapor deposition (PVD), metal organic chemical vapor deposition (MOCVD), electroplating, electroless-plating methods, etc. In the case of depositing copper by using the MOCVD method, an apparatus for supplying a liquid raw material such as a bubbler must be employed because the copper (Cu) raw material must be changed into a liquid state.

The conventional bubbler is constructed so that carrier gases can be supplied to a container in which liquid raw materials, that is, precursors of a liquid state are contained and bubbles generated through mixture with the carrier gases at a constant ratio can be supplied to a process chamber. The ratio by which the carrier gases and the liquid raw material are mixed together is determined by the flow of the carrier gases, and the temperature and pressure within the bubbler.

However, there is a problem with the bubbler as described above because the copper (Cu) raw material has an extremely low vapor pressure and must be maintained at a constant temperature upon deposition. For example, copper (Cu) is deposited using the bubbler, and if the liquid raw material is not maintained at a constant temperature upon deposition then particles are generated due to dissolution of the liquid raw material, which causes degradation of the quality of the copper film to be deposited. In this case, also, it is difficult to reproduce the uniform film quality because the deposition process is repeatedly performed and the throughput of the device is lowered due to low deposition speed.

Due to these problems, a copper (Cu) thin film is deposited using a liquid delivery system including a controller for controlling the amount of precursor to supply and a vaporizer for vaporizing the precursor supplied via the controller. When a liquid raw material (such as a copper (Cu) precursor) which has a low vapor pressure and is easily dissolved is used, the raw material, (i.e., copper), is dissolved at the vaporizer, which causes clogging of the tube in the vaporizer. Therefore, even if the copper (Cu) thin film is deposited using a liquid carrier apparatus, uniform deposition of the thin film is difficult to achieve. Also, in continuous deposition process, the deposition cycle is extremely shortened and reproduction of the thin quality is degraded.

### SUMMARY OF THE INVENTION

An apparatus is provided for supplying a liquid raw material. The apparatus comprises a carrier gas supply tube having a narrowed portion, a sprayer having a nozzle protruding into inside of the narrowed portion of the carrier gas supply tube, a precursor supply tube in communication with the sprayer for supplying a precursor to the sprayer in a liquid state, and a showerhead in communication with an end of the carrier gas supply tube.

Also, a method for manufacturing a copper layer on a semiconductor layer is provided. The method comprises supplying a carrier gas via a carrier gas supply tube having a narrowed portion, supplying a copper precursor in a liquid state via a precursor supply tube and a flow mass control, spraying the copper precursor via a nozzle of a sprayer into the narrowed portion of the carrier gas supply tube, vaporizing the sprayed copper precursor by compression and expansion of the carrier gas, and spraying the vaporized copper precursor via a showerhead so that copper is deposited on the wafer.

### BRIEF DESCRIPTION OF THE DRAWINGS

An example apparatus and method will now be explained in conjunction with the accompanying drawings, wherein:

FIG. 1 is a schematic diagram illustrating an apparatus for supplying a liquid raw material constructed in accordance with the teachings of the present invention; and

FIG. 2 is an enlarged cross-sectional view of a portion “A” of the apparatus shown in FIG. 1.

### DETAILED DESCRIPTION OF THE PREFERRED EMBODIMENTS

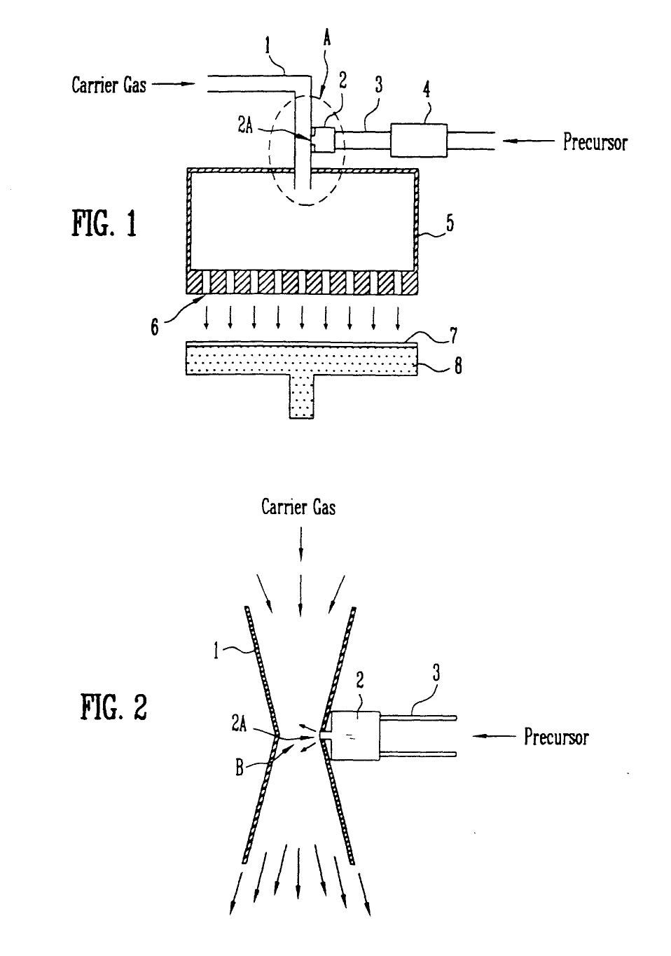

As shown in FIG. 1, a sprayer 2 is connected to a precursor supply tube 3 and to a portion of a carrier gas supply tube 1 from which a carrier gas is supplied. A micro pump or a liquid mass flow controller 4 for supplying an amount of a precursor is connected to the precursor supply tube 3. Also, a showerhead 5 is connected to the end of the carrier gas supply tube 1. A plurality of holes 6 are formed at the bottom of the showerhead 5 so that the precursor in a liquid state can be uniformly sprayed into a process chamber.

Particularly, as shown in FIG. 2, the nozzle 2A in the sprayer 2 is installed so that the nozzle 2A protrudes into the carrier gas supply tube 1. The width of the carrier gas supply tube 1 at the portion in which the nozzle 2A protrudes (indicated by “B”) is formed to be narrower than other portions of the carrier gas supply tube 1 as shown in FIG. 2.

The process of depositing a copper (Cu) thin film by a metal organic chemical vapor deposition (MOCVD) method using an apparatus for supplying a liquid raw material constructed as described above will be explained below.

Carrier gases such as H₂, He, Ar, N₂, etc. are supplied at the flow rate of about 1 to about 5000 standard cubic centimeter per minute (sccm) via the carrier gas supply tube 1, and a copper (Cu) precursor (that is, a copper (Cu) raw material in a liquid state) is supplied via the precursor supply tube 3 in an amount depending on the operation of the flow controller 4. Then, the copper precursor is sprayed into the carrier gas supply tube 1 via the nozzle 2A in the sprayer 2.

The width of the carrier gas supply tube 1 at the portion where the nozzle 2A is installed (indicated by “B”) is narrower than other portions of the carrier gas supply tube 1. Because of this narrowing of the width of the carrier gas supply tube 1, the carrier gas passing through the tube 1 is compressed at the narrowed portion (indicated by “B”). The compressed carrier gas expands again while passing through the narrowed portion (indicated by “B”) and, thus moved rapidly. Therefore, the liquid state copper raw material sprayed out of the nozzle 2A is mixed with the carrier gas by means of expanded volume of the carrier gas so that the copper raw material is vaporized in a gas state of a mist shape.

The copper precursor vaporized above is moved to the surface of the wafer 7 located on the heater block 8 within the process chamber via the showerhead 5 connected to the end of the carrier gas supply tube 1. Then, the copper precursor is chemically reacted so that a copper metal is deposited on the wafer 7.

During the above deposition process, the temperatures of the carrier gas supply tube 1, the precursor supply tube 3 and the sprayer 2 are maintained between about room temperature 20° C. and about 100° C. so that the vaporizing rate can be optimally obtained.

Although the disclosed copper deposition apparatus can be used with any of the copper (Cu) precursors having hfac including (hfac)CuVTMOS, (hfac)CuDMB, and (hfac)CuTMVS series, the apparatus may also use: aluminum (Al), tantalum (Ta), oxide such as TEOS, etc., liquid raw materials such as BST, etc., that are difficult to be vaporized, a catalyst of an iodine (I) containing liquid compound or Hhfac1/2H20, Hhfac, TMVS, pure iodine gas (I2), an iodine (I) containing gas, water vapor, and liquid and gas of group VII element such as F, Cl, Br, I, Ar, etc. and their compounds.

As mentioned above, the precursor can be sufficiently vaporized because the precursor is sprayed into a carrier gas supply tube at a point where the width of the carrier gas supply tube at the portion is narrower than other portions of the carrier gas supply tube 1, so that compression and expansion of the carrier gas are induced.

From the foregoing, a person of ordinary skill in the art will appreciate that the disclosed apparatus and method for supplying a liquid raw material can improve the quality of a deposited film by spraying a sufficiently vaporized precursor, and can preferably maintain reproduction of the quality of the film because of the stabilized nature of the process. Further, the disclosed apparatus can simplify the equipment because the apparatus promotes vaporization without employing an additional vaporizer. This simplification facilitates maintenance of the equipment. Additionally, the disclosed apparatus and method can reduce the consumption amount of precursor and can also prevent degradation of the quality of the film and defects in the film due to clogging of the vaporizer.

From the foregoing, a person of ordinary skill in the art will appreciate that an apparatus has been provided for supplying a liquid raw material. In the disclosed apparatus, a precursor is sprayed into a carrier gas supply tube via a sprayer connected to a given portion of the carrier gas supply tube. The width of the tube at the portion to which the precursor is sprayed is narrower than other portions of the carrier gas supply tube.

Although certain methods and apparatus constructed in accordance with the teachings of the invention have been described herein, the scope of coverage of this patent is not limited thereto. On the contrary, this patent covers all embodiments of the teachings of the invention fairly falling within the scope of the appended claims either literally or under the doctrine of equivalents.

What is claimed is:

1. An apparatus for supplying a liquid raw material comprising:
a carrier gas supply tube having a narrowed portion;
a sprayer having a nozzle protruding into inside of the narrowed portion of the carrier gas supply tube;
a precursor supply tube in communication with the sprayer for supplying a precursor to the sprayer in a liquid state; and
a showerhead in communication with an end of the carrier gas supply tube.

2. The apparatus according to claim 1, further comprising a flow mass controller in communication with the precursor supply tube.

3. A method for manufacturing a copper layer on a semiconductor wafer, comprising the steps of:
supplying a carrier gas via a carrier gas supply tube having a narrowed portion;
supplying a copper precursor in a liquid state via a precursor supply tube and a flow mass control;
spraying the copper precursor via a nozzle of a sprayer into the narrowed portion of the carrier gas supply tube;
vaporizing the sprayed copper precursor by compression and expansion of the carrier gas; and
spraying the vaporized copper precursor via a showerhead so that copper is deposited on the wafer.

4. The method according to claim 3, wherein the carrier gas is one of H₂, He, Ar and N₂ gases and is supplied at the rate of about 1 to about 5000 standard cubic centimeter per minute (sccm).

5. The method according to claim 3, wherein the copper precursor is one of (hfac)CuVTMOS, (hfac)CuDMB and (hfac)CuTMVS series.

6. The method according to claim 3, wherein the temperature the carrier gas supply tube, the precursor supply tube and the sprayer are maintained at between about 20° C. and about 100° C. at least during spraying of the vaporized copper precursor.
